(19) United States
(12) Patent Application Publication
(10) Pub. No.: US 2007/0218197 A1
(43) Pub. Date: Sep. 20, 2007

(54) Vacuum processing system and method of making

(76) Inventor: Yoichi Kurono, Yagoshima (JP)

Correspondence Address: WOOD, HERRON & EVANS, LLP (TOKYO ELECTRON), 2700 CAREW TOWER, 441 VINE STREET, CINCINNATI, OH, 45202, US

(21) Appl. No.: 11/376,724

(22) Filed: Mar. 15, 2006

(51) Int. Cl. B05D 7/22; B05D 1/36; C23C 16/00

(52) U.S. Cl. 427/230; 427/402; 118/723 R

(57) ABSTRACT

A vacuum processing system configured for etch and deposition applications is described. The vacuum processing chamber comprises a monolithic, metal cast chamber having a substrate support pedestal positioned within the chamber by a plurality of pedestal support arms acting as utility conduits for the support pedestal.

### BACKGROUND OF THE INVENTION

1. Field of the Invention

The present invention relates to an apparatus for vacuum processing a substrate and a method of making the apparatus, and more particularly to a vacuum processing chamber and substrate support pedestal therefor and a method of making thereof.

2. Description of Related Art

During semiconductor processing, a (dry) plasma etch process can be utilized to remove or etch material along fine lines or within vias or contacts patterned on a silicon substrate. The plasma etch process generally involves positioning a semiconductor substrate with an overlying patterned, protective mask layer, for example a photoresist layer, in a processing chamber.

Once the substrate is positioned within the chamber, an ionizable, dissociative gas mixture is introduced within the chamber at a pre-specified flow rate, while a vacuum pump is throttled to achieve an ambient process pressure. Thereafter, a plasma is formed when a fraction of the gas species present are ionized by electrons heated via the transfer of radio frequency (RF) power either inductively or capacitively, or microwave power using, for example, electron cyclotron resonance (ECR). Moreover, the heated electrons serve to dissociate some species of the ambient gas species and create reactant specie(s) suitable for the exposed surface etch chemistry.

Once the plasma is formed, selected surfaces of the substrate are etched by the plasma. The process is adjusted to achieve appropriate conditions, including an appropriate concentration of desirable reactant and ion populations to etch various features (e.g., trenches, vias, contacts, etc.) in the selected regions of the substrate. Such substrate materials where etching is required include silicon dioxide (SiO₂), low dielectric constant (i.e., low-k) dielectric materials, poly-silicon, and silicon nitride.

During plasma etching, as well as other plasma processes in semiconductor manufacturing, it is essential to form and maintain a clean, vacuum environment in order to minimize contamination of the substrate and reduce the potential for yield-reducing defects.

### SUMMARY OF THE INVENTION

According to principles of the present invention, provided are an apparatus for vacuum processing a substrate which maintains a clean vacuum environment, a monolithic vacuum processing chamber therefor, and methods of making the apparatus and the chamber.

According to one embodiment, a monolithic, cast metal, vacuum processing chamber is provided having a substrate support pedestal integrally formed of a metal casting.

According to a further embodiment of the invention, a vacuum processing apparatus is provided having a vacuum processing chamber and integral substrate support formed of a metal casting.

According to another embodiment, a vacuum processing system is described, comprising: a monolithic vacuum processing chamber having a vacuum chamber housing; a substrate support pedestal; and one or more pedestal support arms coupling the vacuum chamber housing with the substrate support pedestal, and configured to support the substrate support pedestal, wherein the monolithic vacuum processing chamber is formed from a metal casting.

According to yet another embodiment, a method of fabricating a vacuum processing system is provided comprising: metal casting a monolithic vacuum processing chamber having a vacuum chamber housing; a substrate support pedestal; and one or more pedestal support arms coupling the vacuum chamber housing with the substrate support pedestal and configured to support the substrate support pedestal.

### BRIEF DESCRIPTION OF THE DRAWINGS

In the accompanying drawings:

FIG. 1 shows a cross-sectional view of a vacuum processing chamber according to an embodiment of the present invention;

FIG. 2 shows a perspective view of a portion of a vacuum processing chamber according to an embodiment of the present invention;

FIG. 3 shows a cross-sectional view of a vacuum processing chamber according to another embodiment of the present invention; and

FIG. 4 presents a method of fabricating a vacuum processing chamber according to an embodiment of the present invention.

### DETAILED DESCRIPTION OF PREFERRED EMBODIMENTS

In the following description, in order to facilitate a thorough understanding of the invention and for purposes of explanation and not limitation, specific details are set forth, such as a particular geometry of the vacuum processing system and descriptions of various components. However, it should be understood that the invention may be practiced in other embodiments that depart from these specific details.

In material processing methodologies, pattern etching comprises the application of a thin layer of light-sensitive material, such as photoresist, to an upper surface of a substrate, that is subsequently patterned in order to provide a mask for transferring this pattern to the underlying thin film on a substrate during etching. The patterning of the light-sensitive material generally involves exposure by a radiation source through a reticle (and associated optics) of the light-sensitive material using, for example, a micro-lithography system, followed by the removal of the irradiated regions of the light-sensitive material (as in the case of positive photoresist), or non-irradiated regions (as in the case of negative resist) using a developing solvent.

Thereafter, the pattern formed in the layer of light-sensitive material is transferred to underlying layers using a dry plasma etching process. A vacuum environment is prepared in the plasma processing system, process gases are introduced, and plasma is formed from the process gases, whereby a process chemistry comprising chemically active and physically active species is formed that facilitates the selective etch of the underlying material to which the pattern is transferred. The performance of the process, as well as the overall yield of electronic devices during fabrication, relies in part on the integrity, or cleanliness, of the vacuum environment. For example, any time the number of vacuum sealing devices necessary to couple all of the essential components to the plasma processing environment is reduced, the lesser the probability of infiltration of the processing environment by contaminants.

Known manufacturers have traditionally built vacuum process chambers and plasma processing systems from billets of material, i.e., blocks of aluminum. Those chambers are built at considerable cost due to both the cost of the original material and the cost of machining. In fact, a large portion of the original material often becomes waste in the machining process. In addition, these vacuum chambers are often complex and comprise many sealing surfaces, or locations where contaminants can permeate through the chamber.

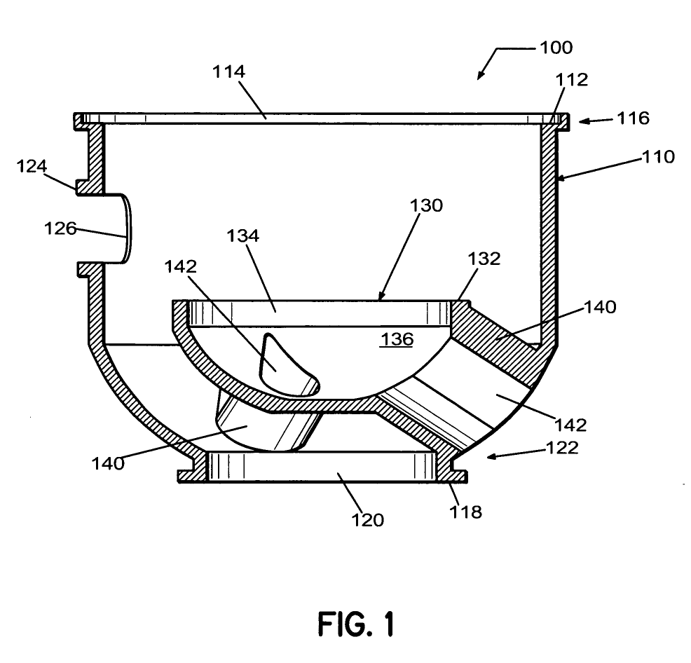

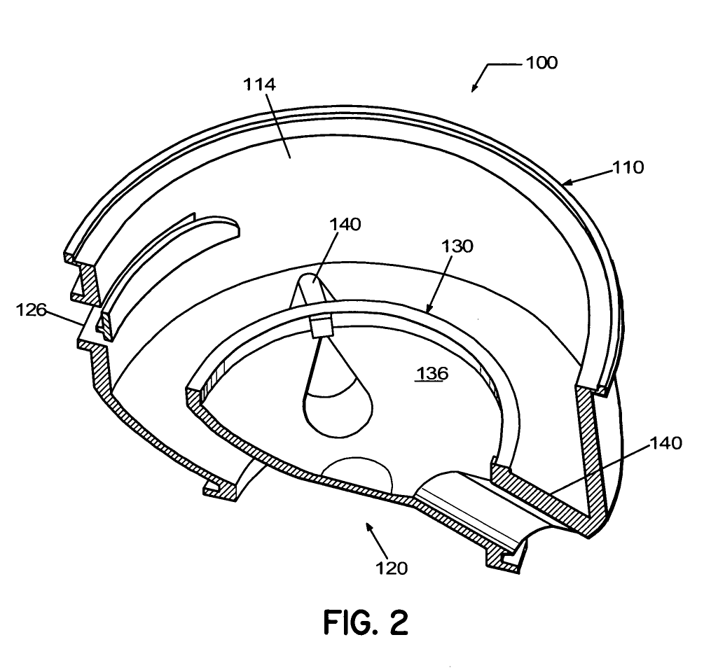

Referring now to the drawings, wherein like reference numerals designate identical or corresponding parts throughout the several views, FIGS. 1 through 3 illustrate a vacuum processing system according to one embodiment. The vacuum processing system comprises a monolithic vacuum processing chamber 100 having a vacuum chamber housing 110, a substrate support pedestal 130, and one or more pedestal support arms 140 coupling the vacuum chamber housing 110 with the substrate support pedestal 130, and configured to support the substrate support pedestal 130, wherein the monolithic vacuum processing chamber 100 is formed from a metal casting. For example, the metal casting can include an aluminum metal casting. As illustrated in FIG. 1, the vacuum chamber housing 110 can be substantially cylindrical. However, other shapes are contemplated, such as rectangular.

Referring still to FIGS. 1 through 3, the vacuum chamber housing 110 comprises a first sealing surface 112 surrounding a first opening 114 at an upper end 116 of the vacuum chamber housing 110 configured to hermetically engage an upper chamber assembly 150. Additionally, the vacuum chamber housing 110 comprises a second sealing surface 118 surrounding a second opening 120 at a lower end 122 of the vacuum chamber housing 110 configured to hermetically engage a lower chamber assembly 160. The first sealing surface 112, or the second sealing surface 118, or both, can include a sealing feature configured to retain a sealing device, such as an elastomeric O-ring.

For example, the upper chamber assembly 150 can comprise a process gas distribution system configured to introduce one or more process gases to a substrate in the vacuum chamber housing 110. The process gases can include any process gas, etch gas, deposition gas, purge gas, etc., utilized in the manufacturing of integrated circuits (ICs) or semiconductor devices.

Alternatively, for example, the upper chamber assembly 150 can comprise a plasma generation system configured to form plasma adjacent a substrate treated within the vacuum chamber housing 110. The plasma generation system can include a capacitively coupled plasma (CCP) source, such as a plate electrode, or it may include an inductively coupled plasma (ICP) source, such as a helical or flat coil. The plasma generation system can also form plasma by using electron cyclotron resonance (ECR), launching of a Helicon wave, or a propagating surface wave. Each plasma source described above is well known to those skilled in the art.

Alternatively, for example, the upper chamber assembly 150 can comprise a radical generation system configured to introduce radicals to a substrate treated within the vacuum chamber housing 110. The radical generation system can include an Astron® reactive gas generator, commercially available from MKS Instruments, Inc., ASTeX® Products (90 Industrial Way, Wilmington, Mass. 01887).

Alternatively yet, for example, the upper chamber assembly 150 can comprise a radiative heating system, such as an array of heating lamps, configured to heat a substrate in the vacuum chamber housing 110, or a vacuum lid assembly configured to be coupled to the vacuum chamber housing 110 and vacuum seal the first opening 114.

Additionally, the upper chamber assembly 150 can include a combination of two or more of the elements described above.

Additionally, for example, the lower chamber assembly 160 can comprise a vacuum pumping system. For example, the vacuum pumping system comprises a vacuum pump 164 to evacuate vacuum chamber housing 110 through a vacuum valve 162 to the desired degree of vacuum, and to remove gaseous species from the vacuum chamber housing 110 during processing. An automatic pressure controller (APC) and an optional trap can be used in series with the vacuum pump. Additionally, an abatement system may be utilized in series with the vacuum pump. The vacuum pump can include a turbo-molecular pump (TMP) capable of a pumping speed up to 5000 liters per second (and greater). Alternatively, the vacuum pump 164 can include a dry roughing pump. During processing, the process gas can be introduced into the vacuum chamber housing 110, and the chamber pressure can be adjusted by the APC. For example, the chamber pressure can range from approximately 1 mTorr to approximately 50 Torr, and in a further example, the chamber pressure can range from about 10 mTorr to about 10 Torr. The APC can utilize vacuum valve 162, which may include a butterfly-type valve, or a gate valve. The trap can collect by-products from the vacuum chamber housing 110, and the abatement system can dissociate, or break down, effluent into more environmentally friendly gases.

Referring still to FIGS. 1 through 3, the vacuum chamber housing 110 comprises a third sealing surface 124 surrounding a transfer opening 126 in the vacuum chamber housing 110 configured to hermetically engage a substrate transfer system (not shown) and permit the passage of a substrate into and out of the vacuum chamber housing 110. The third sealing surface 124 can include a sealing feature configured to retain a sealing device, such as an elastomeric O-ring.

Referring still to FIGS. 1 through 3, the vacuum chamber housing 110 comprises a fourth sealing surface 132 surrounding a utility opening 134 in the substrate support pedestal 130 configured to hermetically engage a substrate holder assembly 180 upon which a substrate 125 rests. The fourth sealing surface 132 can include a sealing feature configured to retain a sealing device, such as an elastomeric O-ring. For example, the substrate holder assembly 180 can comprise an electrostatic chuck (ESC) configured to support substrate 125 and electrically clamp substrate 125 to the electrostatic chuck.

Additionally, for example, the substrate holder assembly 180 can comprise a substrate heating system, a substrate cooling system, a substrate backside gas supply system, a substrate clamping system, a substrate lift system, an electrically powered electrode (such as a radio frequency (RF) powered electrode), or a combination of two or more thereof. The substrate heating system can include a re-circulating fluid flow that transfers heat to the substrate holder assembly 180 and receives heat from a heat exchanger system (not shown), or it may include resistive heating elements, or a combination thereof. The substrate cooling system can include a re-circulating fluid flow that receives heat from the substrate holder assembly 180 and transfers heat to a heat exchanger system (not shown). Additionally, the substrate heating system, or the substrate cooling system, or both, can include thermoelectric devices.

Additionally, the substrate backside gas supply system can be configured to deliver a heat transfer gas, such as helium, to the backside of substrate 125 in order to improve the gas-gap thermal conductance between substrate 125 and substrate holder assembly 180. Such a system can be utilized when temperature control of the substrate is required at elevated or reduced temperatures. For instance, the substrate backside gas supply system can comprise a two-zone gas distribution system, wherein the helium gas gap pressure can be independently varied between the center and the edge of substrate 125. Using the substrate clamping system, the substrate holder assembly 180 can be configured to electrically or mechanically clamp substrate 125 to the substrate holder assembly 180.

Additionally, the substrate lift assembly can be capable of raising and lowering three or more substrate lift pins in order to vertically transfer substrate 125 to and from an upper surface of the substrate holder assembly 180 and a transfer plane in the vacuum chamber housing 110. The three or more substrate lift pins can be coupled to a common lift pin element, that may be translated vertically using a drive mechanism in order to lift substrate 125 to and from the upper surface of substrate holder assembly 180. The drive mechanism (not shown) utilizes, for example, an electric drive system (having an electric stepper motor and threaded rod) or a pneumatic drive system (having an air cylinder), for raising and lowering the common lift pin element. Substrate 125 can be transferred into and out of vacuum chamber housing 110 through transfer opening 126, aligned on the transfer plane, via a robotic transfer system (not shown), and received by the substrate lift pins. Once the substrate 125 is received from the transfer system, it can be lowered to the upper surface of the substrate holder assembly 180 by lowering the substrate lift pins.

Furthermore, the electrically powered electrode can be electrically biased at an RF voltage via the transmission of RF power from an RF generator through an impedance match network to the powered electrode in the substrate holder assembly 180. The RF bias can serve to heat electrons to form and maintain plasma. In this configuration, the system can operate as a reactive ion etch (RIE) reactor or plasma enhanced deposition system, wherein the chamber and an upper gas injection electrode serve as ground surfaces. A typical frequency for the RF bias can range from 0.1 MHz to 100 MHz. RF systems for plasma processing are well known to those skilled in the art.

Alternately, RF power is applied to the powered electrode at multiple frequencies. Furthermore, the impedance match network serves to improve the transfer of RF power to plasma in the vacuum chamber housing by reducing the reflected power. Match network topologies (e.g. L-type, π-type, T-type, etc.) and automatic control methods are well known to those skilled in the art.

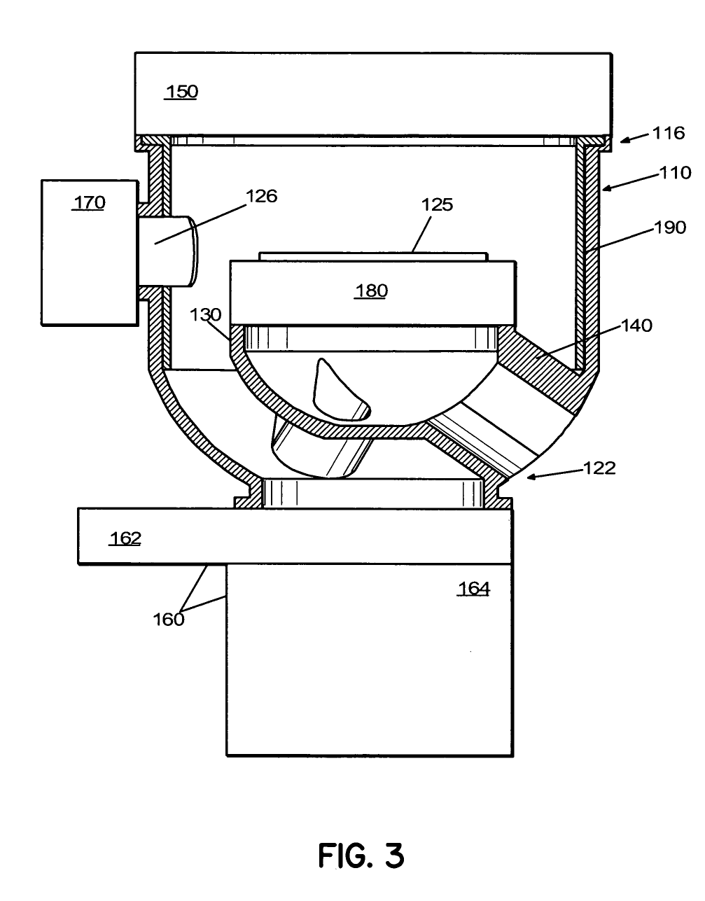

Referring to FIG. 3, a liner 190 may be coupled to the vacuum chamber housing 110 in order to protect the interior surface of the vacuum chamber housing 110. The liner 190 may include a protective barrier, such as a coating, which will be discussed in greater detail below.

Referring still to FIGS. 1 through 3, one or more of the one or more pedestal support arms 140 comprises a hollow passage 142 in order to act as a conduit for making electrical connections, or mechanical connections, or both, between components outside of the vacuum chamber housing 110 and the substrate holder assembly 180. The electrical and/or mechanical connections can be made through the one or more hollow pedestal support arms 140 to the backside of the substrate holder assembly 180 adjacent a cavity 136 in the substrate support pedestal 130. Any one of the elements described above can be packaged within the pedestal cavity 136.

Additionally, any element within monolithic vacuum processing chamber 110 can be coated with a ceramic material, such as aluminum oxide, or yttrium oxide, or a mixture thereof. In one embodiment, the coating comprises at least one of a III-column element (column III of periodic table) and a Lanthanon element. In another embodiment, the III-column element comprises at least one of Yttrium, Scandium, and Lanthanum. In another embodiment, the Lanthanon element comprises at least one of Cerium, Dysprosium, and Europium. For example, any element may be coated with a material selected from the group consisting of Al₂O₃, Sc₂O₃, Sc₂F₃, YF₃, La₂O₃, Y₂O₃, and DyO₃.

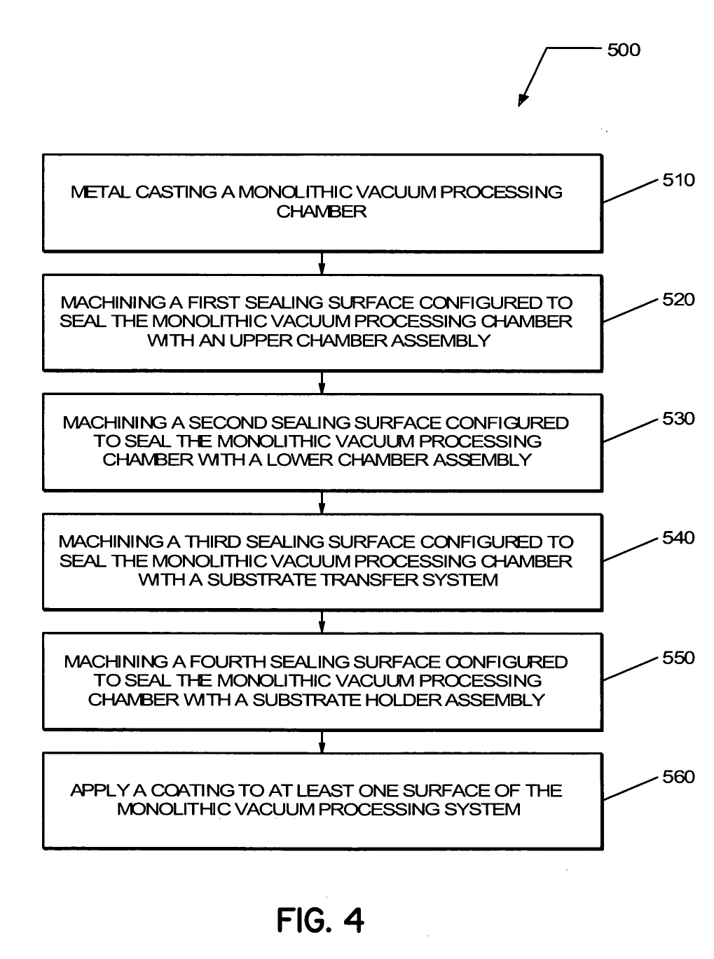

FIG. 4 presents a flow chart of a method for fabricating a vacuum processing chamber according to an embodiment. The flow chart 500 begins in 510 with metal casting a monolithic vacuum processing chamber having a vacuum chamber housing; a substrate support pedestal; and one or more pedestal support arms coupling the vacuum chamber housing with the substrate support pedestal and configured to support the substrate support pedestal. The monolithic vacuum processing chamber can include the process chamber described in FIGS. 1 through 3.

In 520, a first sealing surface is machined on the vacuum chamber housing. For example, the first sealing surface surrounds a first opening at an upper end of the vacuum chamber housing, and it is configured to seal the monolithic vacuum processing chamber with an upper chamber assembly. The first sealing surface can be machined with a sealing feature, such as an O-ring groove, in order to receive a sealing device, such as an elastomeric O-ring.

In 530, a second sealing surface is machined on the vacuum chamber housing. For example, the second sealing surface surrounds a second opening at a lower end of the vacuum chamber housing, and it is configured to seal the monolithic vacuum processing chamber with a lower chamber assembly. The second sealing surface can be machined with a sealing feature, such as an O-ring groove, in order to receive a sealing device, such as an elastomeric O-ring.

In 540, a third sealing surface is machined on the vacuum chamber housing. For example, the third sealing surface surrounds a transfer opening in the vacuum chamber housing, and it is configured to seal the monolithic vacuum processing chamber with a transfer system configured to transfer substrates into and out of the monolithic vacuum processing chamber. The third sealing surface can be machined with a sealing feature, such as an O-ring groove, in order to receive a sealing device, such as an elastomeric O-ring.

In 550, a fourth sealing surface is machined on the vacuum chamber housing. For example, the fourth sealing surface surrounds a utility opening on the substrate support pedestal, and it is configured to seal the substrate support pedestal with a substrate support assembly. The fourth sealing surface can be machined with a sealing feature, such as an O-ring groove, in order to receive a sealing device, such as an elastomeric O-ring.

In 560, at least one surface in the monolithic vacuum processing chamber is protected by a coating. The coating can, for example, include a ceramic material, such as aluminum oxide, or yttrium oxide, or a mixture thereof. In one embodiment, the coating comprises at least one of a III-column element (column III of periodic table) and a Lanthanon element. In another embodiment, the III-column element comprises at least one of Yttrium, Scandium, and Lanthanum. In another embodiment, the Lanthanon element comprises at least one of Cerium, Dysprosium, and Europium. For example, any element may be coated with a material selected from the group consisting of Al₂O₃, Sc₂O₃, Sc₂F₃, YF₃, La₂O₃, Y₂O₃, and DyO₃.

Although only certain embodiments of this invention have been described in detail above, those skilled in the art will readily appreciate that many modifications are possible in the embodiments without materially departing from the novel teachings and advantages of this invention. For example, the monolithic vacuum processing chamber may be utilized with any vacuum processing system or plasma processing system utilized in the manufacture of ICs or semiconductor devices, such as an etching system, a deposition system, a thermal treatment system, a rapid thermal processing system, a chemical treatment system, a drying system, or a material curing system. Accordingly, all such modifications are intended to be included within the scope of this invention.

What is claimed is:

1. A monolithic vacuum processing chamber for a vacuum processing system comprising:
a vacuum chamber housing;
a substrate support pedestal; and
one or more pedestal support arms coupling said vacuum chamber housing with said substrate support pedestal, and configured to support said substrate support pedestal on the housing,
wherein said monolithic vacuum processing chamber is integrally formed of a metal casting.

2. The vacuum processing chamber of claim 1, wherein said metal casting comprises an aluminum metal casting.

3. The vacuum processing chamber of claim 1, wherein said vacuum chamber housing comprises a first sealing surface surrounding a first opening at an upper end of said vacuum chamber housing configured to hermetically engage an upper chamber assembly, and a second sealing surface surrounding a second opening at a lower end of said vacuum chamber housing configured to hermetically engage a lower chamber assembly.

4. A vacuum processing system comprising the vacuum processing chamber of claim 3.

5. The vacuum processing system of claim 4, wherein said upper chamber assembly comprises a process gas distribution system configured to introduce one or more process gases to said substrate in said vacuum chamber housing, a plasma generation system configured to form plasma adjacent a substrate in said vacuum chamber housing, a radical generation system configured to introduce radicals to a substrate in said vacuum chamber housing, a radiative heating system configured to heat a substrate in said vacuum processing system, or a vacuum lid assembly, or a combination of two or more thereof.

6. The vacuum processing system of claim 4, wherein said lower chamber assembly comprises a vacuum pumping system.

7. The vacuum processing system of claim 6, wherein said vacuum pumping system comprises a vacuum valve and a vacuum pump.

8. The vacuum processing chamber of claim 3, wherein said vacuum chamber housing further comprises a third sealing surface surrounding a transfer opening in said vacuum chamber housing configured to hermetically engage a substrate transfer system and permit the passage of a substrate into and out of said vacuum chamber housing.

9. The vacuum processing chamber of claim 1, wherein said substrate support pedestal comprises a fourth sealing surface surrounding a utility opening in said substrate support pedestal configured to hermetically engage a substrate holder assembly.

10. The vacuum processing chamber of claim 9, wherein said substrate holder assembly comprises an electrostatic chuck configured to support a substrate and electrically clamp said substrate to said electrostatic chuck.

11. A vacuum processing system comprising the chamber of claim 9, wherein said substrate holder assembly comprises a substrate heating system, a substrate cooling system, a substrate backside gas supply system, a substrate clamping system, a powered electrode, or a combination of two or more thereof.

12. The vacuum processing chamber of claim 9, wherein one or more of said one or more pedestal support arms is hollow in order to permit the passage of electrical connections, or mechanical connections, or both, from outside of said vacuum chamber housing, through said one or more hollow pedestal support arms, to the backside of said substrate holder assembly adjacent a cavity in said substrate support pedestal.

13. The vacuum processing system comprising the chamber of claim 12, wherein said electrical connections comprise a power connection for an electrostatic clamping system, a power connection for a heating element, a power connection for a cooling element, or a power connection for an RF electrode, or a combination of two or more thereof.

14. The vacuum processing system comprising the chamber of claim 12, wherein said mechanical connections comprise a fluid connection for a heating channel, a fluid connection for a cooling channel, a gas line connection for a substrate backside gas supply system, or a pneumatic gas line for a substrate lift system, or a combination of two or more thereof.

15. The vacuum processing chamber of claim 12, wherein said cavity in said substrate support pedestal facilitates the packaging of a pneumatic substrate lift assembly, or a portion of an impedance matching system for an RF power connection to an RF electrode in said substrate holder assembly.

16. The vacuum processing chamber of claim 3, wherein at least one surface of said monolithic vacuum processing chamber has a coating formed thereon, and wherein said at least one surface excludes said first sealing surface and said second sealing surface.

17. The vacuum processing chamber of claim 16, wherein said coating is an anodic layer.

18. The vacuum processing chamber of claim 16, wherein said coating contains at least one column III element.

19. The vacuum processing chamber of claim 16, wherein said coating contains at least one element selected from the group consisting of Al₂O₃, Sc₂O₃, Sc₂F₃, YF₃, La₂O₃, Y₂O₃, and DyO₃.

20. A method of fabricating a vacuum processing chamber, comprising:
metal casting a monolithic vacuum processing chamber having:
a vacuum chamber housing;
a substrate support pedestal; and
one or more pedestal support arms coupling said vacuum chamber housing with said substrate support pedestal, and configured to support said substrate support pedestal.

21. The method of claim 20, further comprising:
machining a first sealing surface surrounding a first opening at an upper end of said vacuum chamber housing configured to hermetically engage an upper chamber assembly; and
machining a second sealing surface surrounding a second opening at a lower end of said vacuum chamber housing configured to hermetically engage a lower chamber assembly.

22. The method of claim 21, further comprising:
machining a third sealing surface surrounding a transfer opening in said vacuum chamber housing configured to hermetically engage a substrate transfer system and permit the passage of a substrate into and out of said vacuum chamber housing.

23. The method of claim 22, further comprising:
machining a fourth sealing surface surrounding a utility opening in said substrate support pedestal configured to hermetically engage a substrate holder assembly.

24. The method of claim 23, further comprising:
applying a coating to at least one surface of said monolithic vacuum processing chamber, wherein said coating is not applied to said first sealing surface and second sealing surface.
